(19) United States
(12) Patent Application Publication
(10) Pub. No.: US 2026/0136493 A1
(43) Pub. Date: May 14, 2026

(54) ALL-IN-ONE LIQUID COOLER

(71) Applicant: Tsung-Hsien HUANG, I-Lan Hsien (TW)

(72) Inventor: Tsung-Hsien HUANG, I-Lan Hsien (TW)

(21) Appl. No.: 18/988,778

(22) Filed: Dec. 19, 2024

(30) Foreign Application Priority Data
Nov. 13, 2024 (TW) 113143577

(51) Int. Cl. H05K 7/20

(52) U.S. Cl. CPC H05K 7/20272; H05K 7/20254; H05K 7/20263

(57) ABSTRACT

An all-in-one liquid cooler includes a liquid-cooling radiator and a cold plate. The liquid-cooling radiator has a first liquid box, a second liquid box, and a heat dissipation pipe assembly connected between the first and second liquid boxes. The cold plate is combined with the second liquid box to be attached to a processor. The first liquid box of the liquid-cooling radiator forms a cold liquid chamber and a hot liquid chamber. There is a flow dividing baffle in the cold liquid chamber with multiple through holes. After the liquid enters the cold liquid chamber, it is first dispersed through the through holes and then flows to the cold plate, so that the liquid is evenly distributed in the heat dissipation pipe assembly to fully dissipate heat.

### BACKGROUND OF THE INVENTION

### 1. Field of the Invention

The present invention relates to the field of liquid cooling device technology, and in particular to an all-in-one liquid cooler for cooling and dissipating heat from a processor.

### 2. Description of the Related Art

Liquid coolers used in computers and servers today are usually split type coolers, including separate liquid-cooling radiator, cold plate and liquid pump, which are connected by multiple liquid pipes to form a closed circulation system. However, the split type has an uncompact structure and is inconvenient to install. To this end, the inventor of this case has proposed a variety of all-in-one liquid cooler designs. The all-in-one liquid cooler has a liquid pump inside a liquid-cooling radiator and a cold plate at the bottom. The cold plate can be installed on a processor to achieve the function of a liquid cooling processor.

However, the conventional structure design of liquid-cooling radiators may cause the liquid to be not evenly distributed and flow through each liquid pipe, resulting in uneven heat dissipation efficiency. Specifically, when the coolant flow rate is larger in some liquid pipes and smaller in others, the heat cannot be removed effectively, resulting in lower heat dissipation efficiency in some areas. This uneven circulation can cause an unbalanced temperature distribution in the processor, affecting its stability and performance.

On the other hand, if the liquid flow rate is too fast, although the total flow rate of the cooler can be increased, the liquid does not have enough residence time to effectively absorb heat when flowing through the heat dissipation pipes and cold plate. As a result, the heat cannot be fully transferred to the coolant, resulting in insufficient overall heat dissipation. The ideal situation is to maintain an appropriate flow rate so that the liquid has enough time to absorb the heat, but not so slow that the flow rate affects the circulation efficiency of the coolant. Therefore, how to improve the above-mentioned defects of the prior art is the subject that the present invention is intended to actively overcome.

### SUMMARY OF THE INVENTION

The main object of the present invention is to provide an all-in-one liquid cooler to solve the problems of uneven flow rate and excessive flow rate of liquid in each heat dissipation pipe of the traditional liquid cooler, so that the liquid can flow evenly through each heat dissipation pipe and dissipate heat fully.

Another object of the present invention is to provide an all-in-one liquid cooler to solve the problem that the hot liquid flowing out of the cold plate will be thermally transferred to the adjacent cold liquid, thereby ensuring that the cold liquid flows into the cold plate at a low temperature.

In order to achieve the above objects, the present invention proposes an all-in-one liquid cooler, the preferred technical solution of which includes: a liquid-cooling radiator and a cold plate. The liquid-cooling radiator has a first liquid box, a second liquid box and a heat dissipation pipe assembly. The heat dissipation pipe assembly has a plurality of first row pipes, second row pipes and heat dissipation fins. The first row pipes and the second row pipes are flat metal tubes whose two ends are respectively connected to the first liquid box and the second liquid box. The heat dissipation fins are respectively disposed outside the first row pipes and the second row pipes. The top surface of the cold plate is coupled to the outside of the bottom wall of the first liquid box, and the bottom surface of the cold plate is used to adhere to the surface of a processor. The first liquid box has a first box body and a first box cover. The upper end of the first box body is concave to form a first chamber, and the interior of the first chamber is divided into a cold liquid chamber and a hot liquid chamber by a heat-resisting structure. The bottoms of the cold liquid chamber and the hot liquid chamber are connected to the interior of the cold plate through a cold liquid hole and a hot liquid hole, respectively. The first box cover covers the upper end of the first box body, and the top wall of the first box cover is provided with a plurality of first row pipe insertion holes connected to the cold liquid chamber and the hot liquid chamber. The lower ends of the first row pipes and the second row pipes are respectively inserted into the first row pipe insertion holes. A flow dividing baffle is provided in the cold liquid chamber, and the flow dividing baffle is provided with a plurality of through holes connecting the two sides thereof. The flow dividing baffle enables the liquid flowing into the cold liquid chamber from the first row of pipes to be dispersed through the plurality of through holes and then flow into the interior of the cold plate through the cold liquid hole.

The all-in-one liquid cooler of the present invention can achieve the following effects:
(I) Slowing down the flow rate of the cooling liquid: The flow dividing baffle has multiple through holes, which can slow down the speed of the cooling liquid flowing into the cold plate. This helps to increase the residence time of the liquid in the first row pipes, improve the heat exchange efficiency between the liquid and the heat dissipation fins, and fully cool the liquid.
(II) Uniform cooling: The flow dividing baffle can help the liquid to be evenly distributed in the first row pipes, ensuring that the cold liquid can flow evenly through each first row pipe, so that the liquid can dissipate heat evenly, thereby improving the overall heat dissipation efficiency.
(III) Preventing heat transfer from hot liquid to cold liquid: Through the design of the heat-resisting structure, the hot liquid flowing into the hot liquid chamber cannot be heat-transferred to the cold liquid in the adjacent cold liquid chamber, thereby preventing the cooled cold liquid from being heated again.

### BRIEF DESCRIPTION OF THE DRAWINGS

FIG. 1 is a three-dimensional schematic diagram of the all-in-one liquid cooler of the present invention.

FIG. 2 is an exploded schematic diagram of the liquid-cooling radiator and cold plate of the present invention.

FIG. 3 is an exploded schematic diagram of the liquid-cooling radiator of the present invention.

FIG. 4 is a schematic longitudinal section diagram of the all-in-one liquid cooler of FIG. 1 of the present invention.

FIG. 5 is a partial exploded schematic diagram of the first liquid box of the liquid-cooling radiator of the present invention.

FIG. 6 is a fully exploded schematic diagram of the first liquid box of the liquid-cooling radiator of the present invention.

FIG. 7 is a schematic diagram of the decomposition of the flow dividing baffle and the heat-resisting structure of the present invention.

FIG. 8 is an exploded schematic diagram of the second liquid box of the liquid-cooling radiator of the present invention.

### DETAILED DESCRIPTION OF THE PREFERRED EMBODIMENT

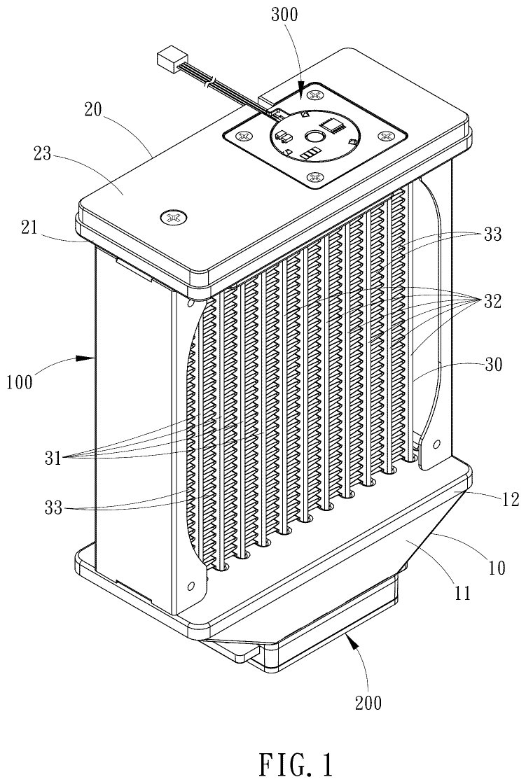

Referring to FIG. 1, the present invention is an all-in-one liquid cooler, and a preferred embodiment thereof comprises a liquid-cooling radiator 100, a cold plate 200, and a liquid pump 300.

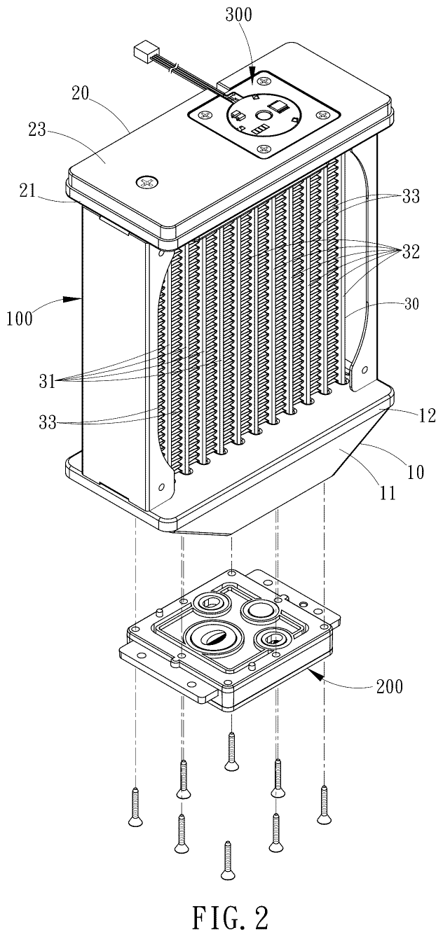

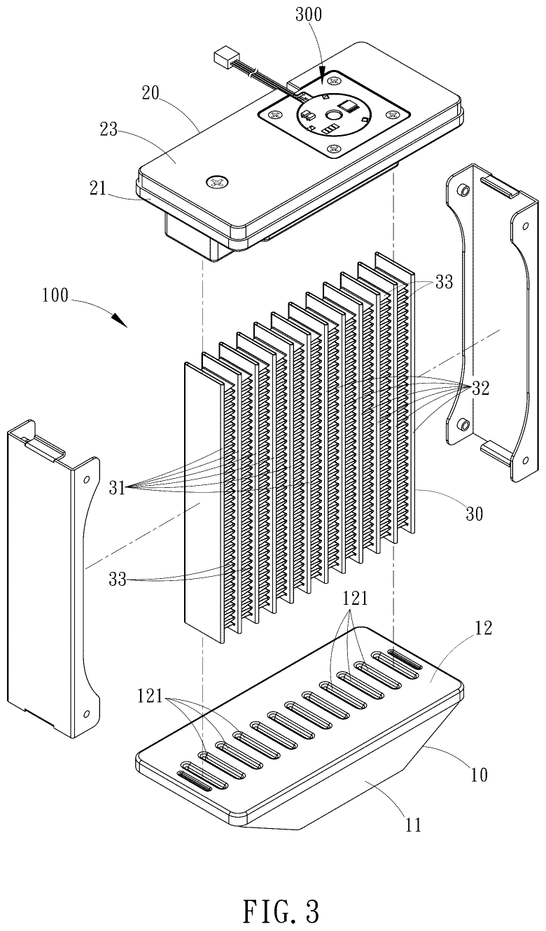

Referring also to FIG. 2 and FIG. 3, the liquid-cooling radiator 100 comprises a first liquid box 10, a second liquid box 20, and a heat dissipation pipe assembly 30.

The first liquid box 10 and the second liquid box 20 are hollow boxes made of heat dissipation metal (such as aluminum alloy) and are used to inject a working liquid (water or other cooling liquid) into the first liquid box 10 and the second liquid box 20. The heat dissipation pipe assembly 30 comprises a plurality of first row pipes 31, a second row pipes 32 and heat dissipation fins 33 arranged in parallel and at intervals. The first row pipes 31 and the second row pipes 32 are flat metal pipes, and their two ends are respectively connected to the first liquid box 10 and the second liquid box 20. The heat dissipation fins 33 are respectively disposed outside the first row pipes 31 and the second row pipes 32.

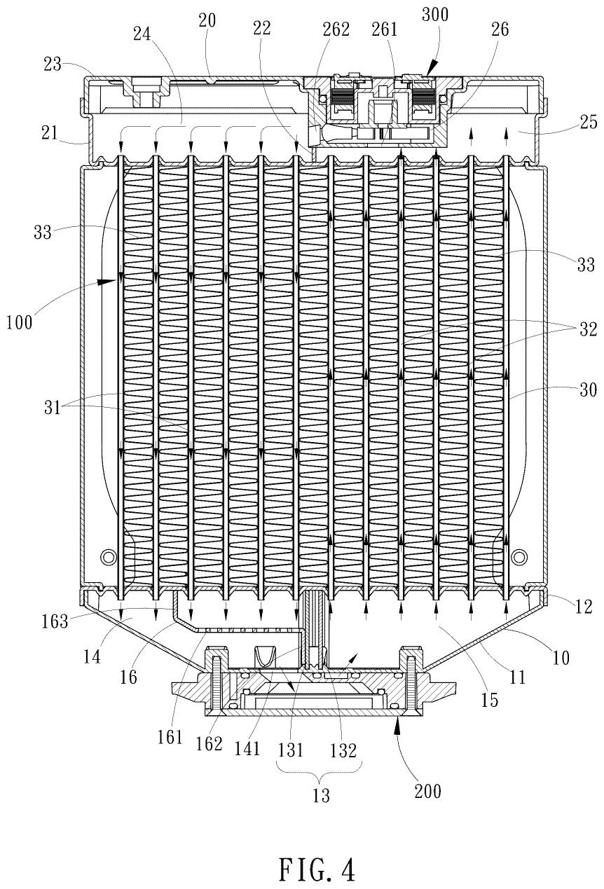

One side of the cold plate 200 is coupled to the outside of the bottom wall of the first liquid box 10, so that the bottom wall of the first liquid box 10 is directly connected to the cold plate 200 through a connecting structure. The other side of the cold plate 200 is used to be attached to a chip processor (not shown) to cool the chip processor. The liquid pump 300 is disposed in the second liquid box 20 to drive the working liquid in the liquid-cooling radiator 100 to circulate among the first liquid box 10, the second liquid box 20, the heat dissipation pipe assembly 30 and the cold plate 200 in sequence (as shown in FIG. 4).

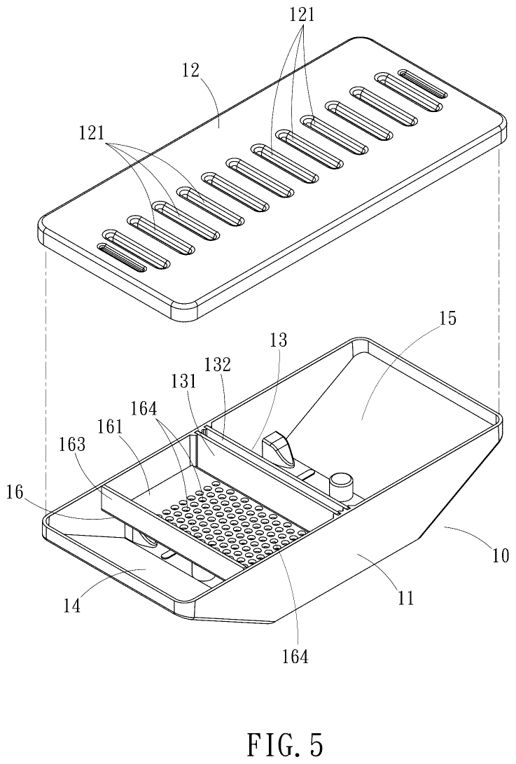

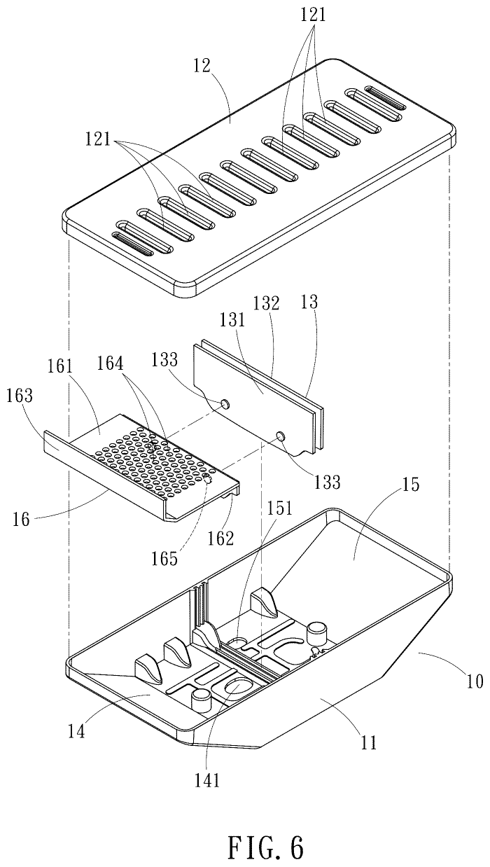

Referring to FIGS. 5 and 6, the first liquid box 10 of the present invention comprises a first box body 11 and a first box cover 12 in a preferred embodiment. The first box body 11 is a box body formed by stamping of an aluminum alloy, and its upper end is concave to form a first chamber. The interior of the first chamber is divided into a cold liquid chamber 14 and a hot liquid chamber 15 by a heat-resisting structure 13. The bottom of the cold liquid chamber 14 and the bottom of the hot liquid chamber 15 are connected to the interior of the cold plate 200 through a cold liquid hole 141 and a hot liquid hole 151 respectively (as shown in FIG. 4). The first box cover 12 is a cover body formed by integral stamping of aluminum alloy, which covers and is welded to the box opening at the upper end of the first box body 11. The top wall of the first box cover 12 is provided with a plurality of first row pipe insertion holes 121 connected to the cold liquid chamber 14 and the hot liquid chamber 15, so that the lower ends of the first row pipes 31 and the second row pipes 32 are respectively inserted into the first row pipe insertion holes 121, so that one end (lower end) of each of the first row pipes 31 can be connected to the cold liquid chamber 14, and one end (lower end) of each of the second row pipes 32 can be connected to the hot liquid chamber 15. The present invention further provides a flow dividing baffle 16 in the cold liquid chamber 14, and the flow dividing baffle 16 is provided with a plurality of through holes 164 connecting the two sides thereof. Through the setting of the flow dividing baffle 16, the liquid (cold liquid) flowing into the cold liquid chamber 14 from the first row of pipes 31 first passes through the plurality of through holes 164 to complete flow rate regulation, and then flows into the interior of the cold plate 200 through the cold liquid hole 141.

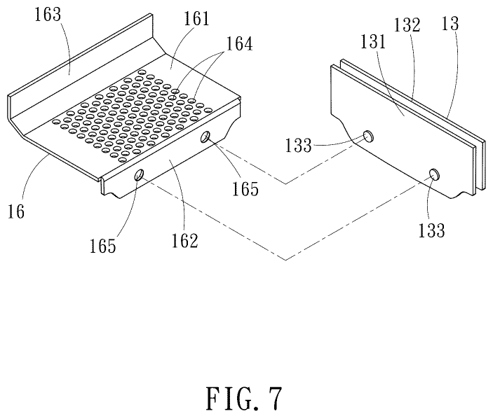

Referring also to FIG. 6 and FIG. 7, the flow dividing baffle 16 is preferably an aluminum alloy plate formed by bending in one piece, and comprises a first plate 161 corresponding to the first row pipe insertion holes 121 of the first box cover 12, a second plate 162 connected to one end of the first plate 161, and a third plate 163 connected to the other end of the first plate 161. The bending directions and angles of the second plate 162 and the third plate 163 can be adjusted according to the internal space of the first box body 11 and are not limited. In one of the preferred implementations, the second plate 162 is combined and fixed to one side of the heat-resisting structure 13, and the end of the third plate 163 is combined and fixed (e.g., welded) to the inner surface of the first box cover 12 (FIG. 4). Thus, a plurality of through holes 164 are provided on the first plate 161, so that a majority of the through holes 164 correspond to the first row pipe insertion holes 121 (one end of the first row pipes 31). The arrangement and range of the plurality of through holes 164 can be changed according to the demand for regulating the water flow. The plurality of through holes 164 can also be disposed on the second plate 162 or the third plate 163. The second plate 162 on one side of the flow dividing baffle 16 can be welded to one side of the heat-resisting structure 13 through a welding structure, and the welding method is CAB furnace brazing or aluminum alloy vacuum chamber welding. Alternatively, as shown in FIG. 6 and FIG. 7, two positioning holes 165 may be provided on one side of the second plate 162 corresponding to the heat-resisting structure 13, and two positioning protrusions 133 may be provided on one side of the heat-resisting structure 13. During assembly, the positioning protrusions 133 are embedded in the positioning holes 165, thereby fixing the flow dividing baffle 16 on one side of the heat-resisting structure 13. If necessary, welding can also be carried out through the above welding method.

Referring to FIGS. 4, 5 and 6, the heat-resisting structure 13 preferably comprises a cold liquid baffle 131 and a hot liquid baffle 132. The cold liquid baffle 131 and the hot liquid baffle 132 are arranged in parallel and spaced apart in the first chamber of the first box body 11 to divide the first chamber into the cold liquid chamber 14 and the hot liquid chamber 15. Moreover, the peripheries of the cold liquid baffle 131 and the hot liquid baffle 132 are welded to the inner wall of the first chamber and the inner wall of the first box cover 12 by the above-mentioned welding method. Thereby, the second plate 162 of the flow dividing baffle 16 can be combined and fixed to one side of the cold liquid baffle 131 by the above-mentioned assembly or welding structure.

Through the above structural design, the present invention can utilize the multiple through holes 164 of the flow dividing baffle 16 to control the flow rate of the liquid (cold liquid) flowing into the cold plate 200. By controlling the flow rate in this way, the residence time of the liquid in the first row pipes 31 is increased, and the heat exchange efficiency between the liquid and the heat dissipation fins 33 is improved, so that the liquid is fully cooled, thereby improving the cooling effect on the processor. Moreover, the flow dividing baffle 16 can help the liquid to be evenly distributed in the first row pipes 31, ensuring that the liquid (cold liquid) can flow evenly through each first row pipe 31. By controlling the uniform flow of the liquid, it is possible to avoid the situation where the liquid flows too fast in a certain row pipe, so that the liquid can dissipate heat evenly, thereby improving the overall heat dissipation efficiency. In addition, the present invention forms a heat-resisting space between the cold liquid baffle 131 and the hot liquid baffle 132 through the design of the heat-resisting structure 13, so that the hot liquid flowing into the hot liquid chamber 15 cannot be thermally transferred to the cold liquid in the adjacent cold liquid chamber 14, thereby preventing the cooled cold liquid from being heated again, thereby improving the cooling efficiency of the cold plate.

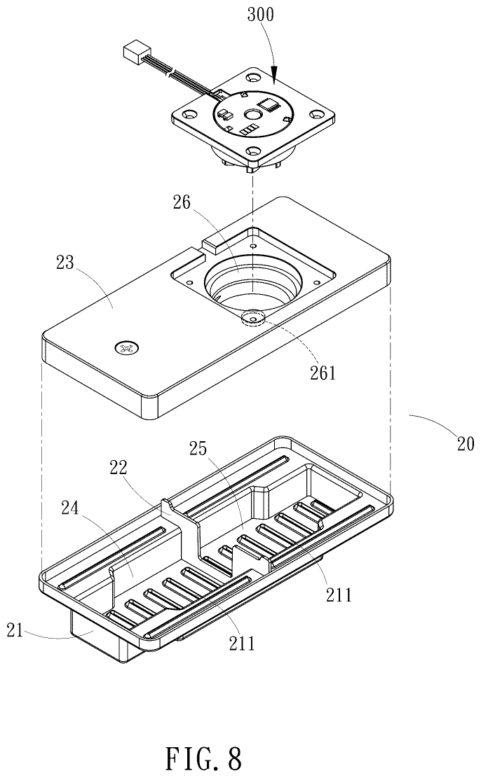

Referring again to FIGS. 2 to 4 and 8, the second liquid box 20 of the present invention can preferably be implemented as a structure for installing the liquid pump 300, which comprises a second box body 21, a second partition 22 and a second box cover 23. The upper end of the second box body 21 is concave to form a second chamber. The second partition 22 is disposed inside the second chamber to divide the second chamber into a liquid outlet chamber 24 and a liquid inlet chamber 25. The bottom wall of the second box body 21 is provided with a plurality of second row pipe insertion holes 211 connected to the liquid outlet chamber 24 and the liquid inlet chamber 25, and the upper ends of the first row pipes 31 and the second row pipes 32 are respectively inserted into the second row pipe insertion holes 211, so that the upper ends of the first row pipes 31 and the second row pipes 32 are respectively connected to the liquid outlet chamber 24 and the liquid inlet chamber 25. The second box cover 23 covers the box opening at the upper end of the second box body 21. The second box cover 23 is provided with a seat body protruding into the liquid inlet chamber 25, and a liquid pump installation chamber 26 is formed in the seat body. The liquid pump installation chamber 26 is provided with a liquid inlet hole 261 connected to the liquid inlet chamber 25, and a liquid outlet hole 262 connected to the liquid outlet chamber 24. The liquid pump 300 is a known component. The liquid pump 300 is installed in the liquid pump installation chamber 26 so that the liquid pump 300 is located in the liquid inlet chamber 25 of the second liquid box 20 and can pump liquid for circulation, thereby forming an all-in-one liquid cooler containing the liquid pump 300.

Although a particular embodiment of the invention has been described in detail for purposes of illustration, various modifications and enhancements may be made without departing from the spirit and scope of the invention. Accordingly, the invention is not to be limited except as by the appended claims.

1. An all-in-one liquid cooler, comprising a liquid-cooling radiator and a cold plate, wherein:
said liquid-cooling radiator comprises a first liquid box, a second liquid box and a heat dissipation pipe assembly, said heat dissipation pipe assembly comprising a plurality of first row pipes, a plurality of second row pipes and a plurality of heat dissipation fins, said first row pipes and said second row pipes being flat metal pipes with respective two opposite ends connected to said first liquid box and said second liquid box respectively, said heat dissipation fins being respectively disposed outside said first row pipes and said second row pipes, said first liquid box comprising a first box body, a first box cover and a heat-resisting structure, said first box body having an upper end thereof recessed to form a first chamber, and the interior of said first chamber being divided into a cold liquid chamber and a hot liquid chamber by said heat-resisting structure, said cold liquid chamber having a cold liquid hole located on a bottom thereof and connected to the inside of said cold plate, said hot liquid chamber having a hot liquid hole located on a bottom thereof and connected to the inside of said cold plate, said first box cover covering the upper end of said first box body, said first box cover comprising a plurality of first row pipe insertion holes located on a top wall thereof and connected to said cold liquid chamber and said hot liquid chamber, said first row pipes and said second row pipes having respective lower ends thereof respectively inserted into said first row pipe insertion holes, said cold liquid chamber being provided with a flow dividing baffle, said flow dividing baffle being provided with a plurality of through holes connecting two opposite sides thereof, said flow dividing baffle allowing a liquid flowing into said cold liquid chamber from said first row pipes to first pass through said plurality of through holes and then flow into the interior of said cold plate through said cold liquid hole; and
said cold plate comprises a top surface bonded to an outside of a bottom wall of said first liquid box, and an opposing bottom surface used to attach to the surface of a processor.

2. The all-in-one liquid cooler as claimed in claim 1, wherein said flow dividing baffle is a metal plate formed by bending in one piece, and comprises a first plate corresponding to said first row pipe insertion holes of said first box cover, a second plate connected to one end of said first plate and a third plate connected with one end thereof to an opposite end of said first plate, said second plate being bonded and fixed to one side of said heat-resisting structure, said third plate having an opposite end thereof coupled to and fixed to an inner surface of said first box cover.

3. The all-in-one liquid cooler as claimed in claim 2, wherein said plurality of through holes are disposed on one of said first plate, said second plate and said third plate.

4. The all-in-one liquid cooler as claimed in claim 2, wherein said second plate is welded to one side of said heat-resisting structure.

5. The all-in-one liquid cooler as claimed in claim 4, wherein said heat-resisting structure comprises a cold liquid baffle and a hot liquid baffle, said cold liquid baffle and said hot liquid baffle being arranged in parallel in said first chamber, said cold liquid baffle and said hot liquid baffle having the peripheries thereof welded to an inner wall of said first chamber and an inner wall of said first box cover; said second plate of said flow dividing baffle is coupled and fixed to one side of said cold liquid baffle.

6. The all-in-one liquid cooler as claimed in claim 2, wherein said second plate comprises two positioning holes located on one side thereof corresponding to said heat-resisting structure, and said heat-resisting structure comprises two positioning protrusions located on one side thereof and respectively embedded in said positioning holes.

7. The all-in-one liquid cooler as claimed in claim 6, wherein said heat-resisting structure comprises a cold liquid baffle and a hot liquid baffle, said cold liquid baffle and said hot liquid baffle being arranged in parallel in said first chamber, said cold liquid baffle and said hot liquid baffle having the peripheries thereof welded to an inner wall of said first chamber and an inner wall of said first box cover; said second plate of said flow dividing baffle is coupled and fixed to one side of said cold liquid baffle.

8. The all-in-one liquid cooler as claimed in claim 1, wherein said second liquid box comprises a second box body, a second partition and a second box cover, said second box body having an upper end thereof recessed to form a second chamber, said second partition being located inside said second chamber to divide said second chamber into a liquid outlet chamber and a liquid inlet chamber, said second box body comprising a plurality of second row pipe insertion holes located on a bottom wall thereof and connected to said liquid outlet chamber and said liquid inlet chamber; said first row pipes and said second row pipes have respective upper ends thereof respectively inserted into said second row pipe insertion holes, so that the upper ends of said first row pipes and said second row pipes are connected to said liquid outlet chamber and said liquid inlet chamber respectively; said second box cover covers a box opening at the upper end of said second box body.

9. The all-in-one liquid cooler as claimed in claim 8, further comprising a liquid pump disposed in said liquid inlet chamber of said second liquid box.
